(19) United States
(12) Patent Application Publication
(10) Pub. No.: US 2023/0109843 A1
(43) Pub. Date: Apr. 13, 2023

(54) PHOTOSENSITIVE RESIN COMPOSITION AND CURED FILM PREPARED THEREFROM

(71) Applicant: ROHM AND HAAS ELECTRONIC MATERIALS KOREA LTD., Chungcheongnam-do (KR)

(72) Inventors: Jong Han YANG, Gyeonggi-do (KR); Geun HUH, Gyeonggi-do (KR); Jin KWON, Gyeonggi-do (KR); Jong-Ho NA, Gyeonggi-do (KR)

(21) Appl. No.: 18/065,798

(22) Filed: Dec. 14, 2022

Related U.S. Application Data
(63) Continuation of application No. 16/097,883, filed on Oct. 31, 2018, now abandoned.

(30) Foreign Application Priority Data
May 19, 2016 (KR) 10-2016-0061371
Mar. 28, 2017 (KR) 10-2017-0039208

(51) Int. Cl. G03F 7/075; G03F 7/023; G03F 7/038; G03F 7/004; G03F 7/32

(52) U.S. Cl. CPC G03F 7/0758; G03F 7/0233; G03F 7/0381; G03F 7/0045; G03F 7/0757; G03F 7/322; G03F 7/038; G02F 2201/40

(57) ABSTRACT

The present invention provides a photosensitive resin composition and a cured film prepared therefrom. The photosensitive resin composition includes a mixture of two or more siloxane polymers having different dissolution rates with respect to an aqueous solution of tetramethylammonium hydroxide. The composition keeps high transparency and high sensitivity, which are advantages of a composition containing a siloxane polymer, and has excellent chemical resistance, thereby providing a cured film having excellent stability in a post-processing.

### CLAIM OF BENEFIT OF PRIOR APPLICATION

This application claims priority under 35 U.S.C. § 120 from U.S. patent application Ser. No. 16/097,883 filed Oct. 31, 2018, which is the Convention Filing of KR10-2016-0061371, filed May 19, 2016 and KR 10-2017-0039208, filed Mar. 28, 2017, all of which are incorporated by reference herein in their entirety.

### TECHNICAL FIELD

The present invention relates to a photosensitive resin composition and a cured film prepared therefrom. More particularly, the present invention relates to a photosensitive resin composition which has high transparency and excellent chemical resistance, and a cured film prepared therefrom that can be used in a liquid crystal display or an organic light-emitting (EL) display.

### BACKGROUND ART

Generally, a transparent planarization film is formed on a thin film transistor (TFT) substrate for the purpose of insulation to prevent the contact between a transparent electrode and a data line in a liquid crystal display or an organic EL display. Through a transparent pixel electrode positioned near the data line, the aperture ratio of a panel may be increased and high luminance/resolution may be attained. In order to form such a transparent planarization film, several processing steps are employed to impart a specific pattern profile, and a positive-type photosensitive resin composition is widely employed in this process since fewer processing steps are required. Particularly, a positive-type photosensitive resin composition containing a siloxane polymer is well known as a material having high heat resistance, high transparency, and low dielectric constant.

Korean Laid-open Patent Publication No. 2006-059202 discloses a composition including a siloxane polymer containing a phenolic hydroxyl group in an amount ratio of 20 mole % or less, a quinonediazide compound that contains no methyl group in the ortho- or para-position relative to the phenolic hydroxyl group therein, and a compound containing an alcoholic hydroxyl group and/or a cyclic compound containing a carbonyl group as a solvent, wherein a cured film prepared from the composition has at least 95% transmittance and satisfies a specific chromaticity coordinate.

However, a planarization film prepared using a conventional positive-type photosensitive composition containing such a siloxane composition or a display device employing same may have limitations such as swelling or delamination of the film from a substrate when the cured film is immersed in, or comes into contact with, a solvent, an acid, a base, and the like which are used in a post-processing. Further, in line with the increasing requirement on the high sensitivity and in order to decrease a processing time, the concentration of a solvent, an acid, an alkali, and the like used in a post-processing becomes higher than before, and the requirement on a photosensitive resin composition, which may form a cured film having good chemical resistance, is increasing.

### DISCLOSURE OF INVENTION

### Technical Problem

Accordingly, it is an object of the present invention to provide a photosensitive resin composition which may form a highly transparent cured film having excellent chemical resistance to chemicals (solvent, acid, alkali, and the like) which are used in a post-processing, and also provide a cured film prepared therefrom which is used in a liquid crystal display or an organic EL display.

### Solution to Problems

The present invention provides a photosensitive resin composition, comprising:

(A) a mixture of two or more siloxane polymers having different dissolution rates with respect to an aqueous solution of tetramethylammonium hydroxide,

(B) a 1,2-quinonediazide compound, and

(C) an epoxy compound,

wherein the (A) mixture of siloxane polymers comprises (A-1) a first siloxane polymer which has a dissolution rate of 400 to 2,000 Å/sec when pre-cured with respect to an aqueous solution of 2.38 wt % tetramethylammonium hydroxide; and (A-2) a second siloxane polymer which has a dissolution rate of 1,900 to 8,000 Å/sec when pre-cured with respect to an aqueous solution of 1.5 wt % tetramethylammonium hydroxide.

### Advantageous Effects of Invention

The photosensitive resin composition of the present invention includes a mixture of two or more siloxane polymers having different dissolution rates with respect to an aqueous solution of tetramethylammonium hydroxide (TMAH), and may keep the conventional properties of high sensitivity and satisfy excellent chemical resistance when compared to a single siloxane polymer having the same degree of dissolution rate. That is, due to the use of two or more siloxane polymers having different dissolution rates, the photosensitive resin composition of the present invention may lead to good retention rate and high resolution, thereby forming a cured film having chemical resistance and high sensitivity.

Accordingly, the cured film prepared therefrom may be useful as a film constituting a liquid crystal display or an organic EL display.

### BEST MODE FOR CARRYING OUT THE INVENTION

The photosensitive resin composition according to the present invention includes (A) a mixture of two or more siloxane polymers having different dissolution rates with respect to an aqueous solution of TMAH, (B) a 1,2-quinonediazide compound, and (C) an epoxy compound, and may optionally further include (D) a solvent, and/or (E) a surfactant.

Hereinafter, the photosensitive resin composition will be explained in detail for each component.

In the present disclosure, “(meth)acryl” means “acryl” and/or “methacryl”, and “(meth)acrylate” means “acrylate” and/or “methacrylate”.

(A) Mixture of Siloxane Polymers

The mixture of siloxane polymers (polysiloxanes) is a mixture of two or more siloxane polymers having different dissolution rates with respect to an aqueous solution of TMAH after pre-curing. Such siloxane polymers may form positive-type patterns via the processes of exposure and development. The solubility of the siloxane polymers may be compared on the basis of the solubility with respect to an aqueous solution of TMAH, and the siloxane polymers having high solubility with respect to an aqueous solution of TMAH may be used as a raw material for the preparation of siloxane resin with high sensitivity.

Meanwhile, in case that a cured film is formed by post-curing a photosensitive resin composition including a siloxane polymer at the temperature of about 230° C., it is required to have chemical resistance with respect to an etching solution of indium zinc oxide (IZO) or a rework solution, which is used after forming an organic film. Without securing chemical resistance, the etching solution or the rework solution may penetrate into the cured film to induce the swelling of the cured film. Even though the thickness of the cured film may be recovered returned to the original one before swelling when additional post-curing is performed, defects of generating cracks may arise in an inorganic film such as IZO which is deposited on the organic film. As described above, an etching solution or rework solution may be easily penetrated into a cured film which is formed using a siloxane polymer having high solubility with respect to an aqueous solution of TMAH, and it is hard satisfy both high sensitivity and good chemical resistance.

In the present invention, two or more kinds of siloxane polymers are used where at least one siloxane polymer having a significantly rapid dissolution rate relative to an aqueous solution of 1.5 wt % TMAH is mixed with at least one siloxane polymer having a common dissolution rate relative to an aqueous solution of 2.38 wt % TMAH. For example, the mixture of siloxane polymers (A) includes (A-1) a first siloxane polymer having a dissolution rate of 400 to 2,000 Å/sec after pre-curing with respect to an aqueous solution of 2.38 wt % TMAH; and (A-2) a second siloxane polymer having a dissolution rate of 1,900 to 8,000 Å/sec after pre-curing with respect to an aqueous solution of 1.5 wt % TMAH.

The dissolution rate of the single siloxane polymer and the mixture of the siloxane polymers with respect to an aqueous solution of TMAH may be measured as follows: a siloxane polymer specimen is added to propylene glycol monomethyl ether acetate (PGMEA, solvent) so that the solid content is 17 wt %, and stirred and dissolved using a stirrer at room temperature for 1 hour to prepare a siloxane polymer solution. Then, 3 cc of the siloxane polymer solution thus prepared was dropped on the central part of a 6-inch silicon wafer with a thickness of 525 μm using a pipette in a clean room under the conditions of a temperature of 23.0±0.5° C. and a humidity of 50±5.0%, and the wafer was spin coated to give a coated film having a thickness of 2±0.1 μm. Then, the silicon wafer is heated on a hot plate at 105° C. for 90 seconds to remove solvents, and the film thickness of a cured film is measured using a spectroscopic ellipsometer (Woollam Colo.). A dissolution rate is measured from the silicon wafer having the cured film by measuring a thickness with respect to dissolution time using an aqueous solution of 2.38 wt % TMAH or an aqueous solution of 1.5 wt % TMAH by a thin film analyzer (TFA-11CT, Shinyoung Colo.).

The siloxane polymers (first siloxane polymer, second siloxane polymer, and the like) include a silane compound and/or the condensate of the hydrolysate thereof. In this case, the silane compound or the hydrolysate thereof may be a mono- to tetra-functional silane compounds. As a result, the siloxane polymer may include siloxane structural units selected from the following Q, T, D and M types.

Q type siloxane structural unit: a siloxane structural unit including a silicon atom and four adjacent oxygen atoms, which may be derived from e.g., a tetrafunctional silane compound or the hydrolysate of a silane compound having four hydrolysable groups.

T type siloxane structural unit: a siloxane structural unit including a silicon atom and three adjacent oxygen atoms, which may be derived from e.g., a trifunctional silane compound or the hydrolysate of a silane compound having three hydrolysable groups.

D type siloxane structural unit: a siloxane structural unit including a silicon atom and two adjacent oxygen atoms, which may be derived from e.g., a difunctional silane compound or the hydrolysate of a silane compound having two hydrolysable groups.

M type siloxane structural unit: a siloxane structural unit including a silicon atom and one adjacent oxygen atom, which may be derived from e.g., a monofunctional silane compound or the hydrolysate of a silane compound having one hydrolysable group.

For example, the siloxane polymer may include at least one structural unit derived from a silane compound represented by the following formula 2. In particular, each of the first siloxane polymer and the second siloxane polymer may be a silane compound represented by the following formula 2 and/or the condensate of the hydrolysate thereof.

(R₃)ₙSi(OR₄)₄₋ₙ [Formula 2]

In formula 2, R₃ may be alkyl having 1 to 12 carbon atoms, alkenyl having 2 to 10 carbon atoms, or aryl having 6 to 15 carbon atoms, in the case where a plurality of R₃ is present in the same molecule, each R₃ may be the same or different, in the case where R₃ is alkyl, alkenyl, or aryl, hydrogen atoms may be partially or wholly substituted and R₃ may include a structural unit having a heteroatom;

R₄ is hydrogen, alkyl having 1 to 6 carbon atoms, acyl having 2 to 6 carbon atoms, or aryl having 6 to 15 carbon atoms, in the case where a plurality of R₄ is present in the same molecule, each R₄ may be the same or different, in the case where R₄ is alkyl, acyl, or aryl, hydrogen atoms may be partially or wholly substituted; and

n is an integer of 0 to 3.

Examples of R₃ including the structural unit having a heteroatom may include ether, ester and sulfide.

The silane compound may be a tetrafunctional silane compound where n is 0, a trifunctional silane compound where n is 1, a difunctional silane compound where n is 2, and a monofunctional silane compound where n is 3. Particular examples of the silane compound may include, e.g., as the tetrafunctional silane compounds, tetraacetoxysilane, tetramethoxysilane, tetraethoxysilane, tetrabutoxysilane, tetraphenoxysilane, tetrabenzyloxysilane, and tetrapropoxysilane; as the trifunctional silane compounds, methyltrimethoxysilane, methyltriethoxysilane, methyltriisopropoxysilane, methyltributoxysilane, ethyltrimethoxysilane, ethyltriethoxysilane, ethyltriisopropoxysilane, ethyltributoxysilane, butyltrimethoxysilane, pentafluorophenyltrimethoxysilane, phenyltrimethoxysilane, phenyltriethoxysilane, d³-methyltrimethoxysilane, nonafluorobutylethyltrimethoxysilane, trifluoromethyltrimethoxysilane, n-propyltrimethoxysilane, n-propyltriethoxysilane, n-butyltriethoxysilane, n-hexyltrimethoxysilane, n-hexyltriethoxysilane, decyltrimethoxysilane, vinyltrimethoxysilane, vinyltriethoxysilane, 3-methacryloxypropyltrimethoxysilane, 3-methacryloxypropyltriethoxysilane, 3-acryloxypropyltrimethoxysilane, 3-acryloxypropyltriethoxysilane, p-hydroxyphenyltrimethoxysilane, 1-(p-hydroxyphenyl)ethyltrimethoxysilane, 2-(p-hydroxyphenyl)ethyltrimethoxysilane, 4-hydroxy-5-(p-hydroxyphenylcarbonyloxy)pentyltrimethoxysilane, trifluoromethyltriethoxysilane, 3,3,3-trifluoropropyltrimethoxysilane, 3-aminopropyltrimethoxysilane, 3-aminopropyltriethoxysilane, 3-glycidoxypropyltrimethoxysilane, 3-glycidoxypropyltriethoxysilane, 2-(3,4-epoxycyclohexyl)ethyltrimethoxysilane, 2-(3,4-epoxycyclohexyl)ethyltriethoxysilane, [(3-ethyl-3-oxetanyl)methoxy]propyltrimethoxysilane, 1(3-ethyl-3-oxetanyl)methoxylpropyltriethoxysilane, 3-mercaptopropyltrimethoxysilane, and 3-trimethoxysilylpropylsuccinic acid; as the difunctional silane compounds, dimethyldiacetoxysilane, dimethyldimethoxysilane, diphenyldimethoxysilane, diphenyldiethoxysilane, diphenyldiphenoxysilane, dibutyldimethoxysilane, dimethyldiethoxysilane, (3-glycidoxypropyl)methyldimethoxysilane, (3-glycidoxypropyl)methyldiethoxysilane, 3-(2-aminoethylamino)propyldimethoxymethylsilane, 3-aminopropyldiethoxymethylsilane, 3-chloropropyldimethoxymethylsilane, 3-mercaptopropyldimethoxymethylsilane, cyclohexyldimethoxymethylsilane, diethoxymethylvinylsilane, dimethoxymethylvinylsilane, and dimethoxydi-p-tolylsilane; and as the monofunctional silane compounds, trimethylmethoxysilane, trimethylethoxysilane, tributylmethoxysilane, tributylethoxysilane, (3-glycidoxypropyl)dimethylmethoxysilane, and (3-glycidoxypropyl)dimethylethoxysilane.

Preferred among the tetrafunctional silane compounds are tetramethoxysilane, tetraethoxysilane, and tetrabutoxysilane; preferred among the trifunctional silane compounds are methyltrimethoxysilane, methyltriethoxysilane, methyltriisopropoxysilane, methyltributoxysilane, phenyltrimethoxysilane, ethyltrimethoxysilane, ethyltriethoxysilane, ethyltriisopropoxysilane, ethyltributoxysilane, butyltrimethoxysilane, 3-glycidoxypropyltrimethoxysilane, 3-glycidoxypropyltriethoxysilane, 2-(3,4-epoxycyclohexyl)ethyltrimethoxysilane, and 2-(3,4-epoxycyclohexyl)ethyltriethoxysilane; preferred among the difunctional silane compounds are dimethyldimethoxysilane, diphenyldimethoxysilane, diphenyldiethoxysilane, diphenyldiphenoxysilane, dibutyldimethoxysilane, and dimethyldiethoxysilane.

Such silane compounds may be used alone or in combination of two or more thereof.

The conditions for preparing the hydrolysate of the silane compound represented by formula 2 or the condensate thereof are not specifically limited. For example, the desired hydrolysate or the condensate may be prepared by diluting the silane compound of formula 2 in a solvent such as ethanol, 2-propanol, acetone, and butyl acetate; adding thereto water necessary for the reaction and, as a catalyst, an acid (e.g., hydrochloric acid, acetic acid, nitric acid, oxalic acid, and the like) or a base (e.g., ammonia, triethylamine, cyclohexylamine, TMAH, and the like); and then stirring the mixture thus obtained to complete the hydrolytic polymerization reaction.

The weight average molecular weight of the condensate (siloxane polymer) obtained by the hydrolytic polymerization of the silane compound of formula 2 is preferably in a range of 500 to 50,000, and within this range, the photosensitive resin composition may have desirable film forming properties, solubility, and dissolution rates in a developer.

The kinds or amounts of the solvent, and the acid or base catalyst used for the preparation of the hydrolysate or the condensate thereof may be optionally selected without limitation. The hydrolytic polymerization may be carried out at a low temperature of 20° C. or less, but the reaction may also be promoted by heating or refluxing. The time required for the reaction may vary according to the kind or concentration of a silane monomer, the reaction temperature, and the like. Generally, the reaction time required for obtaining a condensate having a weight average molecular weight of about 500 to 50,000 is in a range of 15 minutes to 30 days; however, the reaction time in the present invention is not limited thereto.

The siloxane polymer may include a linear siloxane structural unit (i.e., D type siloxane structural unit). The linear siloxane structural unit may be derived from a difunctional silane compound, for example, a silane compound of formula 2 where n is 2. In particular, the siloxane polymer may include the structural unit derived from the silane compound of formula 2 where n is 2 in the amount of 0.5 to 50 mol %, and preferably, 1 to 30 mol % on the basis of the mole of Si atoms. Within this range, a cured film may maintain a constant hardness and exhibit flexibility, thereby further improving crack resistance to external stress.

The siloxane polymer may include a structural unit derived from a silane compound of formula 2 where n is 1 (i.e., T type structural unit). For example, the siloxane polymer may include the structural unit derived from the silane compound of formula 2 where n is 1, in a ratio of 40 to 85 mol %, and preferably, 50 to 80 mol % on the basis of the mole of Si atoms. Within the molar range, the photosensitive resin composition may be more advantageous to form a more precise pattern.

In addition, the siloxane polymer may preferably include a structural unit derived from a silane compound having an aryl group in consideration of the hardness, sensitivity and retention rate of a cured film. For example, the siloxane polymer may include a structural unit derived from a silane compound having an aryl group in a molar ratio of 30 to 70 mol %, and preferably 35 to 50 mol % on the basis of the mole of Si atoms. Within the range, the compatibility of a siloxane polymer and an 1,2-quinonediazide compound (B) is good, and thus the excessive decrease in sensitivity may be prevented while attaining more favorable transparency of a cured film The structural unit derived from the silane compound having an aryl group as R₃ may be a structural unit derived from a silane compound of formula 2 where R₃ is aryl, preferably, a silane compound of formula 2 where n is 1 and R₃ is aryl, and particularly, a silane compound of formula 2 where n is 1 and R₃ is phenyl (i.e., T-phenyl type structural unit).

The siloxane polymer may include a structural unit derived from a silane compound of formula 2 where n is 0 (i.e., Q type structural unit). For example, the siloxane polymer may include the structural unit derived from the silane compound of formula 2 where n is 0 in a molar ratio of 10 to 40 mol %, or 15 to 35 mol % on the basis of the mole of Si atoms. Within the molar range, the photosensitive resin composition may maintain its solubility in an aqueous alkaline solution at a proper degree during forming a pattern, thereby preventing any defects caused by a reduction in the solubility or a drastic increase in the solubility of the composition.

The term “mol % on the basis of the mole of Si atoms” as used herein refers to the percentage of the number of moles of Si atoms contained in a specific structural unit with respect to the total number of moles of Si atoms contained in all of the structural units constituting the siloxane polymer.

The mole amount of the siloxane unit in the siloxane polymer may be measured from the combination of Si-NMR, ¹H-NMR, ¹³C-NMR, IR, TOF-MS, elementary analysis, determination of ash, and the like. For example, in order to measure the mole amount of a siloxane unit having a phenyl group, an Si-NMR analysis is performed on a total siloxane polymer, a phenyl bound Si peak area and a phenyl unbound Si peak area are then analyzed, and the mole amount can thus be computed from the peak area ratio therebetween.

The photosensitive resin composition of the present invention may include the siloxane polymer in an amount ratio of 50 to 95 wt %, and preferably 65 to 90 wt % on the basis of the total solid content excluding solvents. Within the range, the resin composition can maintain its developability at a suitable level, thereby producing a cured film with improved film retention rate and pattern resolution.

The mixture of siloxane polymers may include the second siloxane polymer (A-2) in an amount ratio of 1 to 40 wt %, and preferably, 1 to 20 wt % of on the basis of the total amount of the mixture of siloxane polymers. Within the range, the resin composition can maintain its developability at a suitable level, thereby producing a cured film with improved film retention rate and pattern resolution.

The mixture of siloxane polymers may include the first siloxane polymer (A-1) in an amount ratio of 60 to 99 wt %, and preferably, 80 to 99 wt % on the basis of the total amount of the mixture of siloxane polymers. Within the range, the resin composition can maintain its developability at a suitable level, thereby producing a cured film with improved film retention rate and pattern resolution.

(B) 1,2-Quinonediazide Compound

The photosensitive resin composition according to the present invention includes 1,2-quinonediazide compound (B). The 1,2-quinonediazide compound may be any compound used as a photosensitive agent in the photoresist field.

Examples of the 1,2-quinonediazide compound may include an ester of a phenolic compound with 1,2-benzoquinonediazide-4-sulfonic acid or 1,2-benzoquinonediazide-5-sulfonic acid; an ester of a phenolic compound with 1,2-naphthoquinonediazide-4-sulfonic acid or 1,2-naphthoquinonediazide-5-sulfonic acid; a sulfonamide of a compound in which a hydroxyl group of a phenolic compound is substituted with an amino group with 1,2-benzoquinonediazide-4-sulfonic acid or 1,2-benzoquinonediazide-5-sulfonic acid; a sulfonamide of a compound in which a hydroxyl group of a phenolic compound is substituted with an amino group with 1,2-naphthoquinonediazide-4-sulfonic acid or 1,2-naphthoquinonediazide-5-sulfonic acid; an ester of (2-diazo-1-naphthone-5-sulfonyl chloride). The above compounds may be used alone or in combination of two or more thereof.

Examples of the phenolic compound may include 2,3,4-trihydoxylbenzophenone, 2,4,6-trihydroxybenzophenone, 2,2′,4,4′-tetrahydroxybenzophenone, 2,3,3′,4-tetrahydroxybenzophenone, 2,3,4,4′-tetrahydroxybenzophenone, bis(2,4-dihydroxyphenyl)methane, bis(p-hydroxyphenyl)methane, tri(p-hydroxyphenyl)methane, 1,1,1-tri(p-hydroxyphenyl)ethane, bis(2,3,4-trihydroxyphenyl)methane, 2,2-bis(2,3,4-trihydroxyphenyl)propane, 1,1,3-tris(2,5-dimethyl-4-hydroxyphenyl)-3-phenylpropane, 4,4′-[1-[4-[1-[4-hydroxyphenyl]-1-methylethyl]phenyl]ethylidene]bisphenol, bis(2,5-dimethyl-4-hydroxyphenyl)-2-hydroxyphenylmethane, 3,3,3′,3′-tetramethyl-1,1′-spirobiindene-5,6,7,5′,6′,7′-hexanol, 2,2,4-trimethyl-7,2′,4′-trihydroxyflavane, and the like.

More particular examples of the 1,2-quinonediazide compound may include an ester of 2,3,4-trihydroxybenzophenone and 1,2-naphthoquinonediazide-4-sulfonic acid, an ester of 2,3,4-trihydroxybenzophenone and 1,2-naphthoquinonediazide-5-sulfonic acid, an ester of 4,4′-[1-[4-[1-[4-hydroxyphenyl]-1-methylethyl]phenyl]ethylidene]bisphenol and 1,2-naphthoquinonediazide-4-sulfonic acid, an ester of 4,4′-[1-[4-[1-[4-hydroxyphenyl]-1-methylethyl]phenyl]ethylidene]bisphenol and 1,2-naphthoquinonediazide-5-sulfonic acid, (2-diazo-1-naphthone-5-sulfonyl chloride) ester with 4,4′-[1-[4-[1-(4-hydroxyphenyl)-1-methylethyl]phenyl]ethylidene]bis[phenol], and the like. The above compounds may be used alone or in combination of two or more thereof. By using the aforementioned preferable compounds, the transparency of the photosensitive resin composition may be improved.

The 1,2-quinonediazide compound may be included in the photosensitive resin composition in an amount ranging from 1 to 40 parts by weight, and preferably, 3 to 20 parts by weight on the basis of 100 parts by weight of the mixture of siloxane polymers (A). Within the amount range, the resin composition may form a pattern more readily, without defects such as a rough surface of a coated film and scum at the bottom portion of the pattern upon development.

(C) Epoxy Compound

The photosensitive resin composition of the present invention uses an epoxy compound together with a siloxane polymer so as to increase the internal density of a siloxane binder, to thereby improving the chemical resistance of a cured film prepared therefrom.

The epoxy compound (C) may include the repeating unit of the following formula 1.

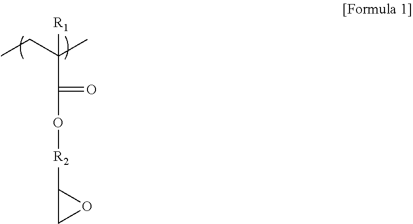

in formula 1,

R₁ is hydrogen or C₁₋₄ alkyl;

R₂ is C₁₋₁₀ alkylene, C₆₋₁₀ arylene, C₃₋₁₀ cycloalkylene, C₃₋₁₀ heterocycloalkylene, C₂₋₁₀ heteroalkylene, R₅—O—R₆,

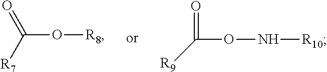

and

R₅ to R₁₀ are each independently C₁₋₁₀ alkylene.

In formula 1, particular examples of R₁ may include hydrogen, methyl, ethyl, propyl, n-butyl, isobutyl and tert-butyl, and preferably include hydrogen or methyl.

Particular examples of R₂ may include methylene, ethylene, propylene, butylene, pentylene, hexylene, heptylene, octylene, nonylene, decylene, phenylene, —C₂H₄—O—C₂H₄—, —C₄H₈—O—C₄H₈—, —C₄H₈—O—CH₂—, —C₄H₈—O—C₂H₄—, —C₂H₄—O—CH₂—, —C₂H₄—COO—C₂H₄—, —C₄H₈—COO—C₄H₈—, —C₄H₈—COO—CH₂—, —C₄H₈—COO—C₂H₄—, —C₂H₄—COO—CH₂—, —C₂H₄—COONH—C₂H₄—, and —C₂H₄—CH(OH)—C₂H₄—, and preferably include methylene or —C₄H₈—O—CH₂—.

The term “homooligomer” used herein means an oligomer having the same repeating unit for polymerization unless otherwise noted, includes a case where two or more kinds of repeating units of formula 1, and includes a case where 90 wt % or more of the repeating unit of formula 1. The epoxy compound (C) of the present invention may be a homooligomer between monomers forming the repeating unit of formula 1.

The compound including the repeating unit of formula 1 used in the present invention may be synthesized by well-known methods.

The epoxy compound may additionally include a structural unit derived from a monomer other than the structural unit (repeating unit) of formula 1.

Particular examples of the structural unit derived from monomers other than the structural unit of formula 1 may include structural units derived from styrene; styrenes having an alkyl substituent such as methylstyrene, dimethylstyrene, trimethylstyrene, ethylstyrene, diethylstyrene, triethylstyrene, propylstyrene, butylstyrene, hexylstyrene, heptylstyrene, and octylstyrene; styrenes having a halogen such as fluorostyrene, chlorostyrene, bromostyrene and iodostyrene; styrenes having an alkoxy substituent such as methoxystyrene, ethoxystyrene, and propoxystyrene; p-hydroxy-α-methylstyrene, acetylstyrene; aromatic ring-containing ethylenically unsaturated compounds such as divinylbenzene, vinylphenol, o-vinylbenzyl methyl ether, m-vinylbenzyl methyl ether, and p-vinylbenzyl methyl ether; unsaturated carboxylic acid esters such as methyl (meth)acrylate, ethyl (meth)acrylate, butyl (meth)acrylate, dimethylaminoethyl (meth)acrylate, isobutyl (meth)acrylate, t-butyl (meth)acrylate, cyclohexyl (meth)acrylate, ethylhexyl (meth)acrylate, tetrahydrofurfuryl (meth)acrylate, hydroxyethyl (meth)acrylate, 2-hydroxypropyl (meth)acrylate, 2-hydroxy-3-chloropropyl (meth)acrylate, 4-hydroxybutyl (meth) acrylate, glycerol (meth)acrylate, methyl α-hydroxymethylacrylate, ethyl α-hydroxymethylacrylate, propyl α-hydroxymethylacrylate, butyl α-hydroxymethylacrylate, 2-methoxyethyl (meth)acrylate, 3-methoxybutyl (meth)acrylate, ethoxy diethylene glycol (meth)acrylate, methoxy triethylene glycol (meth) acrylate, methoxy tripropylene glycol (meth)acrylate, poly(ethyleneglycol) methyl ether (meth)acrylate, phenyl (meth) acrylate, benzyl (meth)acrylate, 2-phenoxyethyl (meth)acrylate, phenoxy diethylene glycol (meth)acrylate, p-nonylphenoxy polyethylene glycol (meth)acrylate, p-nonylphenoxy polypropylene glycol (meth)acrylate, tetrafluoropropyl (meth) acrylate, 1,1,1,3,3,3-hexofluoroisopropyl (meth)acrylate, octafluoropentyl (meth)acrylate, heptadecafluorodecyl (meth)acrylate, tribromophenyl (meth)acrylate, isobornyl (meth)acrylate, dicyclopentanyl (meth)acrylate, dicyclopentetanyl (meth)acrylate, dicyclopentanyloxyethyl (meth)acrylate, and dicyclopentenyloxyethyl (meth)acrylate; tertiary amines having an N-vinyl group such as N-vinyl pyrrolidone, N-vinyl carbazole, and N-vinyl morpholine; unsaturated ethers such as vinyl methyl ether, and vinyl ethyl ether; unsaturated ethers such as allyl glycidyl ether, and 2-methylallyl glycidyl ether; unsaturated imides such as N-phenylmaleimide, N-(4-chlorophenyl)maleimide, N-(4-hydroxyphenyl)maleimide, and N-cyclohexylmaleimide. The structural unit derived from the above exemplary compounds may be included alone or in a combination of two or more in the epoxy compound. Preferably, the styrene-based compounds are preferable in consideration of polymerizability. In particular, in terms of chemical resistance, it is more preferable that the epoxy compound does not contain a carboxyl group, by not using a structural unit derived from a monomer containing a carboxyl group among these compounds.

The structural unit derived from the monomer other than the structural unit of formula 1 may be included in a molar ratio of 1 to 70 mol %, and more preferably, 10 to 60 mol %, on the basis of the total structural unit constituting the epoxy compound. Within the preferable range, a cured film may have desirable hardness.

The epoxy compound may preferably have a weight average molecular weight of 100 to 30,000, and more preferably, 1,000 to 15,000. In the case where the weight average molecular weight of the epoxy compound is 100 or more, the hardness of a thin film may be improved, and in the case where the weight average molecular weight is 30,000 or less, a cured film may have a uniform thickness, which is suitable for planarizing any steps thereon. The weight average molecular weight means a weight average molecular weight using polystyrene standards and measured by gel permeation chromatography (GPC, using tetrahydrofuran as eluent).

In the photosensitive resin composition of the present invention, the epoxy compound (C) may be included in the photosensitive resin composition in an amount of 1 to 40 parts by weight, and preferably, 5 to 27 parts by weight on the basis of 100 parts by weight of the mixture of siloxane polymers (A). Within the amount range, the sensitivity and chemical resistance of the photosensitive resin composition may be improved.

(D) Solvent

The photosensitive resin composition of the present invention may be prepared as a liquid phase composition by mixing the above components with a solvent. The solvent may be, for example, an organic solvent.

The amount of the solvent in the photosensitive resin composition of the present invention is not specifically limited, but may be adjusted to have the solid content of 10 to 70 wt %, and preferably 15 to 60 wt % on the basis of the total weight of the photosensitive resin composition.

The solid content means the constituent components excluding solvents from the resin composition of the present invention. With the amount of the solvent in the amount range, coating may be smoothly performed, and an appropriate degree of flowability may be maintained.

The solvent of the present invention may be any one which can dissolve each component and which is chemically stable, without limitation, and may include, e.g., alcohols, ethers, glycol ether, ethylene glycol alkyl ether acetate, diethylene glycol, propylene glycol monoalkyl ether, propylene glycol alkyl ether acetate, propylene glycol alkyl ether propionate, aromatic hydrocarbons, ketones, esters, and the like.

Particular examples of the solvent may include methanol, ethanol, tetrahydrofuran, dioxane, methyl cellosolve acetate, ethyl cellosolve acetate, ethyl acetoacetate, ethylene glycol monomethyl ether, ethylene glycol monoethyl ether, ethylene glycol dimethyl ether, ethylene glycol diethyl ether, propylene glycol dimethyl ether, propylene glycol diethyl ether, diethylene glycol monomethyl ether, diethylene glycol monoethyl ether, diethylene glycol dimethyl ether, diethylene glycol ethyl methyl ether, propylene glycol monomethyl ether, propylene glycol monoethyl ether, propylene glycol monopropyl ether, dipropylene glycol dimethyl ether, dipropylene glycol diethyl ether, propylene glycol methyl ether acetate, propylene glycol ethyl ether acetate, propylene glycol propyl ether acetate, dipropylene glycol methyl ether acetate, propylene glycol butyl ether acetate, toluene, xylene, methyl ethyl ketone, 4-hydroxy-4-methyl-2-pentanone, cyclopentanone, cyclhexanone, 2-heptanone, γ-butyrolactone, ethyl 2-hydroxypropionate, ethyl 2-hydroxy-2-methylpropionate, ethyl ethoxyacetate, ethyl hydroxyacetate, methyl 2-hydroxy-3-methylbutanoate, methyl 2-methoxypropionate, methyl 3-methoxypropionate, ethyl 3-methoxypropionate, ethyl 3-ethoxypriopionate, methyl 3-ethoxypropionate, methyl pyruvate, ethyl pyruvate, ethyl acetate, butyl acetate, ethyl lactate, butyl lactate, N,N-dimethylformamide, N,N-dimethylacetamide, N-methylpyrrolidone, and the like.

Among the compounds, ethylene glycol alkyl ether acetates, diethylene glycols, propylene glycol monoalkyl ethers, propylene glycol alkyl ether acetates, ketones, and the like are preferably, and diethylene glycol dimethyl ether, diethylene glycol ethyl methyl ether, dipropylene glycol dimethyl ether, dipropylene glycol diethyl ether, propylene glycol monomethyl ether, propylene glycol monoethyl ether, propylene glycol methyl ether acetate, methyl 2-methoxypropionate, γ-butyrolactone, 4-hydroxy-4-methyl-2-pentanone, and the like are particularly preferable.

The above exemplary solvents may be used alone or in combination of two or more thereof.

(E) Surfactant

The photosensitive resin composition of the present invention may further include a surfactant as occasion demands to enhance its coatability.

The kind of the surfactant is not limited, but preferred are fluorine-based surfactants, silicon-based surfactants, non-ionic surfactant and the like.

Particular examples of the surfactants may include fluorine-based surfactants and silicon-based surfactants such as FZ-2122 manufactured by Dow Corning Toray Co., Ltd, BM-1000, and BM-1100 manufactured by BM CHEMIE Co., Ltd., Megapack F-142 D, F-172, F-173, and F-183 manufactured by Dai Nippon Ink Kagaku Kogyo Co., Ltd., Florad FC-135, FC-170 C, FC-430, and FC-431 manufactured by Sumitomo 3M Ltd., Sufron S-112, S-113, S-131, S-141, S-145, S-382, SC-101, SC-102, SC-103, SC-104, SC-105, and SC-106 manufactured by Asahi Glass Co., Ltd., Eftop EF301, EF303, and EF352 manufactured by Shinakida Kasei Co., Ltd., SH-28 PA, SH-190, SH-193, SZ-6032, SF-8428, DC-57, and DC-190 manufactured by Toray Silicon Co., Ltd.; non-ionic surfactants such as polyoxyethylene alkyl ethers such as polyoxyethylene lauryl ether, polyoxyethylene stearyl ether, and polyoxyethylene oleyl ether, polyoxyethylene aryl ethers such as polyoxyethylene octylphenyl ether, and polyoxyethylene nonylphenyl ether, and polyoxyethylene dialkyl esters such as polyoxyethylene dilaurate, and polyoxyethylene distearate; and organosiloxane polymer KP341 (manufactured by Shin-Etsu Kagaku Kogyo Co., Ltd.), (meth)acrylate-based copolymer Polyflow No. 57 and 95 (Kyoei Yuji Kagaku Kogyo Co., Ltd.), and the like. These surfactants may be used alone or in combination of two or more thereof.

The surfactant (E) may be contained in an amount of 0.001 to 5 parts by weight, and preferably 0.05 to 3 parts by weight, based on 100 parts by weight of the mixture of siloxane polymers (A) in the photosensitive resin composition. Within the amount range, the properties of coating and leveling of the composition may be improved.

Besides, other additive components may be additionally included as long as the physical properties of the photosensitive resin composition are not adversely affected.

The photosensitive resin composition of the present invention may be used as a positive-type photosensitive resin composition.

In particular, by using a mixture of two or more siloxane polymers having different dissolution rates with respect to an aqueous solution of TMAH in the present invention, the conventional properties may be maintained and excellent chemical resistance may be satisfied when compared to a single siloxane polymer having the same degree of dissolution rate. In addition, the photosensitive resin composition of the present invention may induce excellent retention rate and high resolution due to the use of two or more siloxane polymers having different dissolution rates, and thus, a cured film having chemical resistance and high sensitivity may be formed.

The present invention also provides a cured film formed from the photosensitive resin composition.

The cured film may be formed by a well-known method in the art, for example, through processes of coating a photosensitive resin composition on a substrate and curing.

The coating may be performed by a method including a spin coating method, a slit coating method, a roll coating method, a screen printing method, an applicator method, and the like, to a desired thickness, e.g., a thickness of 2 to 25 μm.

In particular, for the curing of the photosensitive resin composition, for example, the composition coated on a substrate may be subjected to pre-bake at a temperature of, for example, 60 to 130° C. to remove solvents; then exposed to light using a photomask having a desired pattern; and subjected to development using a developer, for example, a TMAH solution, to form a pattern on the coated film The light exposure may be carried out at an exposure rate of 10 to 200 mJ/cm² based on a wavelength of 365 nm in a wavelength band of 200 to 500 nm. As a light source used for the exposure (irradiation), a low pressure mercury lamp, a high pressure mercury lamp, an extra high pressure mercury lamp, a metal halide lamp, an argon gas laser, etc., may be used; and X-ray, electron beam, etc., may also be used, if desired.

Then, the coated film with a pattern is subjected to post-bake, if necessary, for instance, at a temperature of 150 to 300° C. for 10 minutes to 5 hours to manufacture a desired cured film The cured film thus patterned has excellent physical properties in consideration of chemical resistance, adhesiveness, heat resistance, transparency, dielectricity, solvent resistance, acid resistance and alkali resistance.

Therefore, the cured film has excellent light transmittance without surface roughness when the composition is subjected to heat treatment or is immersed in, or comes into contact with a solvent, an acid, a base, and the like. Thus, the cured film can be used effectively as a planarization film for a TFT substrate of a liquid crystal display or an organic EL display; a partition of an organic EL display; an interlayer dielectric of a semiconductor device; a core or cladding material of an optical waveguide, and the like.

Further, the present invention provides electronic parts including the cured film as a protective film

### MODE FOR THE INVENTION

Hereinafter, the present invention will be explained in detail with reference to examples. However, these examples are only provided to illustrate the present invention, and the scope of the present invention is not limited thereto.

In the following examples, the weight average molecular weight is determined by gel permeation chromatography (GPC) using a polystyrene standard.

### Synthetic Example 1: Synthesis of First Siloxane Polymer (A-1-1)

To a reactor provided with a reflux condenser, 20 wt % of phenyltrimethoxysilane, 30 wt % of methyltrimethoxysilane, 20 wt % of tetraethoxysilane, and 15 wt % of pure water were added, and 15 wt % of propylene glycol monomethyl ether acetate (PGMEA) was added thereto, followed by stirring and refluxing the mixture in the presence of 0.1 wt % of an oxalic acid catalyst for 8 hours, and cooling. Then, the reactant was diluted with PGMEA until the solid content was 30 wt %, and analyzed by GPC. As a result, the weight average molecular weight of the first siloxane polymer (A-1-1) thus synthesized using a polystyrene standard was from 9,000 to 13,000 Da.

A dissolution rate of the siloxane polymer thus synthesized with respect to an aqueous solution of TMAH was measured by the above-mentioned method in the disclosure, and the dissolution rate thereof after pre-curing with respect to an aqueous solution of 2.38 wt % TMAH was 1,959.5 Å/sec.

### Synthetic Example 2: Synthesis of First Siloxane Polymer (A-1-2)

To a reactor provided with a reflux condenser, 40 wt % of phenyltrimethoxysilane, 15 wt % of methyltrimethoxysilane, 20 wt % of tetraethoxysilane, and 20 wt % of pure water were added, and 5 wt % of PGMEA was added thereto, followed by vigorously stirring and refluxing the mixture in the presence of 0.1 wt % of an oxalic acid catalyst for 8 hours, and cooling. Then, the reactant was diluted with PGMEA until the solid content was 40 wt %, and analyzed by GPC. As a result, the weight average molecular weight of the first siloxane polymer (A-1-2) thus synthesized using a polystyrene standard was from 5,000 to 10,000 Da.

A dissolution rate of the siloxane polymer thus synthesized with respect to an aqueous solution of TMAH was measured by the above-mentioned method in the disclosure, and the dissolution rate thereof after pre-curing with respect to an aqueous solution of 2.38 wt % TMAH was 1,483.8 Å/sec.

### Synthetic Example 3: Synthesis of Second Siloxane Polymer (A-2-1)

To a reactor provided with a reflux condenser, 20 wt % of phenyltrimethoxysilane, 30 wt % of methyltrimethoxysilane, 20 wt % of tetraethoxysilane, and 15 wt % of pure water were added, and 15 wt % of PGMEA was added thereto, followed by vigorously stirring and refluxing the mixture in the presence of 0.1 wt % of an oxalic acid catalyst for 7 hours, and cooling. Then, the reactant was diluted with PGMEA until the solid content was 30 wt %, and analyzed by GPC. As a result, the weight average molecular weight of the second siloxane polymer (A-2-1) thus synthesized using a polystyrene standard was from 8,000 to 14,000 Da.

A dissolution rate of the siloxane polymer thus synthesized with respect to an aqueous solution of TMAH was measured by the above-mentioned method in the disclosure, and the dissolution rate thereof after pre-curing with respect to an aqueous solution of 1.5 wt % TMAH was 1,921.7 Å/sec.

### Synthetic Example 4: Synthesis of Second Siloxane Polymer (A-2-2)

To a reactor provided with a reflux condenser, 20 wt % of phenyltrimethoxysilane, 30 wt % of methyltrimethoxysilane, 20 wt % of tetraethoxysilane, and 15 wt % of pure water were added, and 15 wt % of PGMEA was added thereto, followed by vigorously stirring and refluxing the mixture in the presence of 0.1 wt % of an oxalic acid catalyst for 9 hours, and cooling. Then, the reactant was diluted with PGMEA until the solid content was 30 wt %, and analyzed by GPC. As a result, the weight average molecular weight of the second siloxane polymer (A-2-2) thus synthesized using a polystyrene standard was from 13,000 to 19,000 Da.

A dissolution rate of the siloxane polymer thus synthesized with respect to an aqueous solution of TMAH was measured by the above-mentioned method in the disclosure, and the dissolution rate thereof after pre-curing with respect to an aqueous solution of 1.5 wt % TMAH was 7,648.3 Å/sec.

### Synthetic Example 5: Synthesis of First Siloxane Polymer (A-1-3)

To a reactor provided with a reflux condenser, 40 wt % of phenyltrimethoxysilane, 15 wt % of methyltrimethoxysilane, 20 wt % of tetraethoxysilane, and 20 wt % of pure water were added, and 5 wt % of PGMEA was added thereto, followed by vigorously stirring and refluxing the mixture in the presence of 0.1 wt % of an oxalic acid catalyst for 6 hours, and cooling. Then, the reactant was diluted with PGMEA until the solid content was 40 wt %, and analyzed by GPC. As a result, the weight average molecular weight of the first siloxane polymer (A-1-3) thus synthesized using a polystyrene standard was from 5,500 to 10,000 Da.

A dissolution rate of the siloxane polymer thus synthesized with respect to an aqueous solution of TMAH was measured by the above-mentioned method in the disclosure, and the dissolution rate thereof after pre-curing with respect to an aqueous solution of 2.38 wt % TMAH was 480 Å/sec.

### Synthetic Example 6: Synthesis of Siloxane Polymer

To a reactor provided with a reflux condenser, 40 wt % of phenyltrimethoxysilane, 15 wt % of methyltrimethoxysilane, 20 wt % of tetraethoxysilane, and 20 wt % of pure water were added, and 5 wt % of PGMEA was added thereto, followed by vigorously stirring and refluxing the mixture in the presence of 0.1 wt % of an oxalic acid catalyst for 5 hours, and cooling. Then, the reactant was diluted with PGMEA until the solid content was 40 wt %, and analyzed by GPC. As a result, the weight average molecular weight of the siloxane polymer thus synthesized using a polystyrene standard was from 5,000 to 10,000 Da.

A dissolution rate of the siloxane polymer thus synthesized with respect to an aqueous solution of TMAH was measured by the above-mentioned method in the disclosure, and the dissolution rate thereof after pre-curing with respect to an aqueous solution of 2.38 wt % TMAH was 100 Å/sec or less.

### Synthetic Example 7: Synthesis of Second Siloxane Polymer (A-2-3)

To a reactor provided with a reflux condenser, 20 wt % of phenyltrimethoxysilane, 30 wt % of methyltrimethoxysilane, 20 wt % of tetraethoxysilane, and 15 wt % of pure water were added, and 15 wt % of PGMEA was added thereto, followed by vigorously stirring and refluxing the mixture in the presence of 0.1 wt % of an oxalic acid catalyst for 7 hours, and cooling. Then, the reactant was diluted with PGMEA until the solid content was 30 wt %, and analyzed by GPC. As a result, the weight average molecular weight of the second siloxane polymer (A-2-3) thus synthesized using a polystyrene standard was from 10,000 to 15,000 Da.

A dissolution rate of the siloxane polymer thus synthesized with respect to an aqueous solution of TMAH was measured by the above-mentioned method in the disclosure, and the dissolution rate thereof after pre-curing with respect to an aqueous solution of 1.5 wt % TMAH was 4,358.4 Å/sec.

### Synthetic Example 8: Synthesis of Epoxy Compound (C)

A three-necked flask was equipped with a cooling condenser and disposed on a stirrer provided with an automatic temperature regulator. Then, 100 parts by weight of a monomer consisting of glycidyl methacrylate (100 mol %), 10 parts by weight of 2,2′-azobis(2-methylbutyronitrile), and 100 parts by weight of PGMEA were put in the flask, and nitrogen was injected thereto. Then, the solution was slowly stirred and the temperature of the solution was increased to 80° C. and maintained for 5 hours to synthesize an epoxy compound having a weight average molecular weight of about 6,000 to 10,000 Da. Then, PGMEA was added thereto to adjust the solid content thereof to be 20 wt %.

### EXAMPLES AND COMPARATIVE EXAMPLES

### Preparation of Photosensitive Resin Compositions

Using the compounds prepared in the synthetic examples, photosensitive resin compositions according to the following examples and comparative examples were prepared.

In the following examples and comparative examples, the following compounds were used as additional components:

1,2-Quinonediazide compound (B): TPA-517(ester of 2-diazo-1-naphthone sulfonyl chloride), Miwon Commercial Co., Ltd.

Solvent (D-1): PGMEA, Chemtronics Co., Ltd.

Solvent (D-2): gamma-butyrolactone (GBL), BASF Co., Ltd.

Surfactant (E): silicon-based leveling surfactant, FZ-2122, Dow Corning Toray Co., Ltd.

### Example 1

On the basis of 100 parts by weight of a mixture (binder) of 95 wt % of the first siloxane polymer (A-1-1) of Synthetic Example 1 and 5 wt % of the second siloxane polymer (A-2-1) of Synthetic Example 3, 20.8 parts by weight of the epoxy compound (C) of Synthetic Example 8, 4.8 parts by weight of 1,2-quinonediazide compound (B), and 0.1 parts by weight of a surfactant (E) were homogeneously mixed, and dissolved in a solvent (D-1 (PGMEA):D-2 (GBL)=93:7 by weight) so that the solid content was 17 wt %. The product thus obtained was stirred for 1 to 2 hours and filtered with a membrane filter having a pore diameter of 0.2 μm to obtain a photosensitive resin composition of which solid content was 17 wt %.

### Example 2

On the basis of 100 parts by weight of a mixture (binder) of 90 wt % of the first siloxane polymer (A-1-2) of Synthetic Example 2 and 10 wt % of the second siloxane polymer (A-2-1) of Synthetic Example 3, 26.5 parts by weight of the epoxy compound (C) of Synthetic Example 8, 6.1 parts by weight of 1,2-quinonediazide compound (B), and 0.1 parts by weight of a surfactant (E) were homogeneously mixed, and dissolved in a solvent (D-1 (PGMEA):D-2 (GBL)=93:7 by weight) so that the solid content was 17 wt %. The product thus obtained was stirred for 1 to 2 hours and filtered with a membrane filter having a pore diameter of 0.2 μm to obtain a photosensitive resin composition of which solid content was 17 wt %.

### Example 3

On the basis of 100 parts by weight of a mixture (binder) of 97 wt % of the first siloxane polymer (A-1-1) of Synthetic Example 1 and 3 wt % of the second siloxane polymer (A-2-2) of Synthetic Example 4, 20.8 parts by weight of the epoxy compound (C) of Synthetic Example 8, 4.7 parts by weight of 1,2-quinonediazide compound (B), and 0.1 parts by weight of a surfactant (E) were homogeneously mixed, and dissolved in a solvent (D-1 (PGMEA):D-2 (GBL)=93:7 by weight) so that the solid content was 17 wt %. The product thus obtained was stirred for 1 to 2 hours and filtered with a membrane filter having a pore diameter of 0.2 μm to obtain a photosensitive resin composition of which solid content was 17 wt %.

### Example 4

On the basis of 100 parts by weight of a mixture (binder) of 92 wt % of the first siloxane polymer (A-1-2) of Synthetic Example 2 and 8 wt % of the second siloxane polymer (A-2-2) of Synthetic Example 4, 26.5 parts by weight of the epoxy compound (C) of Synthetic Example 8, 6.1 parts by weight of 1,2-quinonediazide compound (B), and 0.1 parts by weight of a surfactant (E) were homogeneously mixed, and dissolved in a solvent (D-1 (PGMEA):D-2 (GBL)=93:7 by weight) so that the solid content was 17 wt %. The product thus obtained was stirred for 1 to 2 hours and filtered with a membrane filter having a pore diameter of 0.2 μm to obtain a photosensitive resin composition of which solid content was 17 wt %.

### Example 5

On the basis of 100 parts by weight of a mixture (binder) of 82 wt % of the first siloxane polymer (A-1-3) of Synthetic Example 5 and 18 wt % of the second siloxane polymer (A-2-2) of Synthetic Example 4, 26.1 parts by weight of the epoxy compound (C) of Synthetic Example 8, 6.0 parts by weight of 1,2-quinonediazide compound (B), and 0.1 parts by weight of a surfactant (E) were homogeneously mixed, and dissolved in a solvent (D-1 (PGMEA):D-2 (GBL)=93:7 by weight) so that the solid content was 17 wt %. The product thus obtained was stirred for 1 to 2 hours and filtered with a membrane filter having a pore diameter of 0.2 μm to obtain a photosensitive resin composition of which solid content was 17 wt %.

### Example 6

On the basis of 100 parts by weight of a mixture (binder) of 94 wt % of the first siloxane polymer (A-1-1) of Synthetic Example 1 and 6 wt % of the second siloxane polymer (A-2-3) of Synthetic Example 7, 20.8 parts by weight of the epoxy compound (C) of Synthetic Example 8, 4.7 parts by weight of 1,2-quinonediazide compound (B), and 0.1 parts by weight of a surfactant (E) were homogeneously mixed, and dissolved in a solvent (D-1 (PGMEA):D-2 (GBL)=93:7 by weight) so that the solid content was 17 wt %. The product thus obtained was stirred for 1 to 2 hours and filtered with a membrane filter having a pore diameter of 0.2 μm to obtain a photosensitive resin composition of which solid content was 17 wt %.

### Comparative Example 1

On the basis of 100 parts by weight of the first siloxane polymer (A-1-1) of Synthetic Example 1, 20.7 parts by weight of the epoxy compound (C) of Synthetic Example 8, 4.7 parts by weight of 1,2-quinonediazide compound (B), and 0.1 parts by weight of a surfactant (E) were homogeneously mixed, and dissolved in a solvent (D-1 (PGMEA):D-2 (GBL)=93:7 by weight) so that the solid content was 17 wt %. The product thus obtained was stirred for 1 to 2 hours and filtered with a membrane filter having a pore diameter of 0.2 μm to obtain a photosensitive resin composition of which solid content was 17 wt %.

### Comparative Example 2

On the basis of 100 parts by weight of the first siloxane polymer (A-1-1) of Synthetic Example 1, 4.1 parts by weight of 1,2-quinonediazide compound (B), and 0.1 parts by weight of a surfactant (E) were homogeneously mixed, and dissolved in a solvent (D-1 (PGMEA):D-2 (GBL)=93:7 by weight) so that the solid content was 17 wt %. The product thus obtained was stirred for 1 to 2 hours and filtered with a membrane filter having a pore diameter of 0.2 μm to obtain a photosensitive resin composition of which solid content was 17 wt %.

### Comparative Example 3

On the basis of 100 parts by weight of a mixture (binder) of 79 wt % of the siloxane polymer of Synthetic Example 6 and 21 wt % of the second siloxane polymer (A-2-2) of Synthetic Example 4, 20.9 parts by weight of the epoxy compound (C) of Synthetic Example 8, 4.8 parts by weight of 1,2-quinonediazide compound (B), and 0.1 parts by weight of a surfactant (E) were homogeneously mixed, and dissolved in a solvent (D-1 (PGMEA):D-2 (GBL)=93:7 by weight) so that the solid content was 17 wt %. The product thus obtained was stirred for 1 to 2 hours and filtered with a membrane filter having a pore diameter of 0.2 μm to obtain a photosensitive resin composition of which solid content was 17 wt %.

### Comparative Example 4

On the basis of 100 parts by weight of a mixture (binder) of 79 wt % of the siloxane polymer of Synthetic Example 6 and 21 wt % of the second siloxane polymer (A-2-2) of Synthetic Example 4, 4.2 parts by weight of 1,2-quinonediazide compound (B), and 0.1 parts by weight of a surfactant (E) were homogeneously mixed, and dissolved in a solvent (D-1 (PGMEA):D-2 (GBL)=93:7 by weight) so that the solid content was 17 wt %. The product thus obtained was stirred for 1 to 2 hours and filtered with a membrane filter having a pore diameter of 0.2 μm to obtain a photosensitive resin composition of which solid content was 17 wt %.

### Comparative Example 5

On the basis of 100 parts by weight of a mixture (binder) of 95 wt % of the first siloxane polymer (A-1-1) of Synthetic Example 1 and 5 wt % of the second siloxane polymer (A-2-1) of Synthetic Example 3, 4.2 parts by weight of 1,2-quinonediazide compound (B), and 0.1 parts by weight of a surfactant (E) were homogeneously mixed, and dissolved in a solvent (D-1 (PGMEA):D-2 (GBL)=93:7 by weight) so that the solid content was 17 wt %. The product thus obtained was stirred for 1 to 2 hours and filtered with a membrane filter having a pore diameter of 0.2 μm to obtain a photosensitive resin composition of which solid content was 17 wt %.

### Experimental Example 1

### Evaluation of Sensitivity

Each of the compositions obtained in the examples and comparative examples was coated on a glass substrate by spin coating, and the coated substrate was pre-baked on a hot plate kept at 110° C. for 90 seconds to remove solvents and to form a dried film The dried film was exposed to light, through a mask having a pattern consisting of square holes in sizes ranging from 2 μm to 25 μm, at an exposure rate to 200 mJ/cm² based on a wavelength of 365 nm for a certain time period using an aligner (model name: MA6), which emits light having a wavelength of 200 nm to 450 nm, and was developed by spraying an aqueous developer of 2.38 wt % TMAH through puddle nozzles at 23° C. The exposed film was then heated in a convection oven at 230° C. for 30 minutes to obtain a cured film having a thickness of 3.0 μm.

The hole size attained by a critical dimension (CD, line width: μm) of the hole pattern formed through a mask having a size of 10 μm with an exposure energy of 40 mJ, was measured. The sensitivity was evaluated as good if the hole size was near 10 μm or greater than 10 μm, and as not good if the hole size was less than 10 μm.

### Experimental Example 2

### Evaluation of Chemical Resistance (Swelling Thickness)

Each of the compositions obtained in the examples and comparative examples was coated on a glass substrate by spin coating and pre-baked on a hot plate kept at 110° C. for 90 seconds to form a dried film having a thickness of 3.1 μm. The dried film was developed with an aqueous solution of 2.38 wt % TMAH through puddle nozzles at 23° C. for 60 seconds. Then, the developed film was exposed through a pattern mask to light at an exposure rate of 200 mJ/cm² based on a wavelength of 365 nm for a certain period using an aligner (model name: MA6), which emits light having a wavelength of 200 nm to 450 nm (bleaching process). The exposed film was then heated in a convection oven at 230° C. for 30 minutes to obtain a cured film The thickness (T1) of the cured film was measured using a non-contact type thickness measuring device (SNU Precision). A rework chemical (product name: LT-360) was introduced to a constant temperature bath and then the temperature was maintained at 50° C. The cured film was immersed in the bath for 2 minutes, washed with deionized water, and the rework chemical was removed by air. Then, the thickness (T2) of the cured film was measured.

The chemical resistance was evaluated from the measured values via the following equation 1 (swelling thickness was calculated after the evaluation experiment for the chemical resistance).

Swelling thickness (Å)=film thickness after immersing into rework chemical (T2)−film thickness before immersing into rework chemical (T1) [Equation 1]

The chemical resistance was recognized as good if the swelling thickness was less than 1,000 A.

### Experimental Example 3

### Evaluation of Adhesion

Each of the photosensitive resin compositions obtained in the examples or comparative examples was coated on a glass substrate via spin coating, and the coated substrate was pre-baked on a hot plate kept at 110° C. for 90 seconds to remove solvents and to form a dried film The dried film was exposed to light, through a mask having a pattern consisting of rod holes in sizes ranging from 1 μm to 25 μm, at an exposure rate to 200 mJ/cm² based on a wavelength of 365 nm for a certain time period using an aligner (model name: MA6), which emits light having a wavelength of 200 nm to 450 nm, and was developed by spraying an aqueous developer of 2.38 wt % TMAH through puddle nozzles at 23° C. The exposed film was then heated in a convection oven at 230° C. for 30 minutes to obtain a cured film having a thickness of 3.0 μm.

In order to evaluate adhesion to the cured film pattern thus formed, the shape of the rod pattern which has a pattern to space ratio of 1:1 and has widths ranging from 1 μm to 10 μm, was observed using an optical microscope (STM6-LM manufactured by Olympus Co., Ltd.). That is, if the distance between patterns of the patterned rod pattern is kept clean and constant, the adhesion of the pattern is recognized to be secured. The smaller the observed pattern size is, the higher the adhesion is.

For reference, the adhesion is ∘ in the case where the size of the smallest pattern securing adhesion is 4 μm or less, Δ for 6μm or less, and X for 8 μm or less.

TABLE 1

| | | | | | | | | | (C) | (B) 1,2- | (D) | | | | Chemical |
|---|---|---|---|---|---|---|---|---|---|---|---|---|---|---|---|
| | | | | | | | | Dissolution | Epoxy | quinonediazide | Solvent | | | | resistance |
| | (A) Siloxane polymer (wt %) | | | | | | | rate on | compound | compound | (weight | | | | (swelling |
| | Syn. | Syn. | Syn. | Syn. | Syn. | Syn. | Syn. | TMAH | (parts by | (parts by | ratio) | | Adhesion | Sensitivity | thickness) |
| | Ex. 1 | Ex. 2 | Ex. 3 | Ex. 4 | Ex. 5 | Ex. 6 | Ex. 7 | (Å/sec) | weight) | weight) | D-1 | D-2 | (μm) | (μm) | (Å) |
| Ex. 1 | 95 | 0 | 5 | 0 | 0 | 0 | 0 | 2211.5 | 20.8 | 4.8 | 93 | 7 | 4 | 10.26 | 350.3 |
| Ex. 2 | 0 | 90 | 10 | 0 | 0 | 0 | 0 | 2035.4 | 26.5 | 6.1 | 93 | 7 | 3 | 10.06 | 450.3 |
| Ex. 3 | 97 | 0 | 0 | 3 | 0 | 0 | 0 | 2200.7 | 20.8 | 4.7 | 93 | 7 | 4 | 10.32 | 675.7 |
| Ex. 4 | 0 | 92 | 0 | 8 | 0 | 0 | 0 | 2165.1 | 26.5 | 6.1 | 93 | 7 | 3 | 10.24 | 840.0 |
| Ex. 5 | 0 | 0 | 0 | 18 | 82 | 0 | 0 | 2193.6 | 26.1 | 6.0 | 93 | 7 | 4 | 9.92 | 575.3 |
| Ex. 6 | 94 | 0 | 0 | 0 | 0 | 0 | 6 | 2261.9 | 20.8 | 4.7 | 93 | 7 | 4 | 10.04 | 464.7 |
| Com. | 100 | 0 | 0 | 0 | 0 | 0 | 0 | 1959.5 | 20.7 | 4.7 | 93 | 7 | 4 | 6.62 | 1929.7 |
| Ex. 1 | | | | | | | | | | | | | | | |
| Com. | 100 | 0 | 0 | 0 | 0 | 0 | 0 | 1959.5 | 0 | 4.1 | 93 | 7 | 8 | 11.90 | 2666.3 |
| Ex. 2 | | | | | | | | | | | | | | | |
| Com. | 0 | 0 | 0 | 21 | 0 | 79 | 0 | 2179 | 20.9 | 4.8 | 93 | 7 | 6 | 10.94 | 1339.3 |
| Ex. 3 | | | | | | | | | | | | | | | |
| Com. | 0 | 0 | 0 | 21 | 0 | 79 | 0 | 2179 | 0 | 4.2 | 93 | 7 | No | No | No |
| Ex. 4 | | | | | | | | | | | | | pattern | pattern | pattern |
| Com. | 95 | 0 | 5 | 0 | 0 | 0 | 0 | 2211.5 | 0 | 4.2 | 93 | 7 | No | No | No |
| Ex. 5 | | | | | | | | | | | | | pattern | pattern | pattern |

As shown in table 1, the compositions of the examples included in the scope of the present invention exhibited equally good chemical resistance, sensitivity and adhesion. On the contrary, the compositions of the comparative examples not included in the scope of the present invention exhibited at least one inferior result.

1. A photosensitive resin composition, comprising:
(A) a mixture of two or more siloxane polymers having different dissolution rates with respect to an aqueous solution of tetramethylammonium hydroxide,
(B) a 1,2-quinonediazide compound, and
(C) an epoxy compound,
wherein the (A) mixture of siloxane polymers comprises (A-1) a first siloxane polymer which has a dissolution rate of 400 to 2,000 Å/sec when pre-cured with respect to an aqueous solution of 2.38 wt % tetramethylammonium hydroxide; and (A-2) a second siloxane polymer which has a dissolution rate of 1,900 to 8,000 Å/sec when pre-cured with respect to an aqueous solution of 1.5 wt % tetramethylammonium hydroxide.

2. The photosensitive resin composition of claim 1, wherein the (C) epoxy compound comprises a repeating unit of the following formula 1: 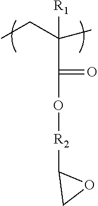
in formula 1,
R₁ is hydrogen or C₁₋₄ alkyl;
R₂ is C₁₋₁₀ alkylene, C₆₋₁₀ arylene, C₃₋₁₀ cycloalkylene, C₃₋₁₀ heterocycloalkylene, C₂₋₁₀ heteroalkylene, R₅—O—R₆, 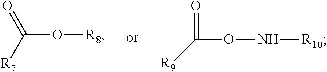
and
R₅ to R₁₀ are each independently C₁₋₁₀ alkylene.

3. The photosensitive resin composition of claim 1, wherein the (A) mixture of siloxane polymers comprises 1 to 40 wt % of the (A-2) second siloxane polymer on the basis of the total weight of the mixture of siloxane polymers.

4. The photosensitive resin composition of claim 1, wherein the siloxane polymer comprises a structural unit derived from a silane compound represented by the following formula 2:
(R₃)ₙSi(OR₄)₄₋ₙ [Formula 2]
in formula 2, R₃ is alkyl having 1 to 12 carbon atoms, alkenyl having 2 to 10 carbon atoms, or aryl having 6 to 15 carbon atoms, in the case where a plurality of R₃ is present in the same molecule, each R₃ may be the same or different, in the case where R₃ is alkyl, alkenyl, or aryl, hydrogen atoms may be partially or wholly substituted and R₃ may include a structural unit having a heteroatom,
R₄ is hydrogen, alkyl having 1 to 6 carbon atoms, acyl having 2 to 6 carbon atoms, or aryl having 6 to 15 carbon atoms, in the case where a plurality of R₄ is present in the same molecule, each R₄ may be the same or different, in the case where R₄ is alkyl, acyl, or aryl, hydrogen atoms may be partially or wholly substituted, and
n is an integer of 0 to 3.

5. The photosensitive resin composition of claim 4, wherein the siloxane polymer comprises a constituent unit derived from a silane compound of formula 2 where n is 0.
